(19) United States
(12) Patent Application Publication
(10) Pub. No.: US 2024/0044941 A1
(43) Pub. Date: Feb. 8, 2024

(54) Probe Card and Method of Manufacturing Thereof

(71) Applicant: Nippon Telegraph and Telephone Corporation, Tokyo (JP)

(72) Inventors: Ai Yanagihara, Musashino-shi, Tokyo (JP); Keita Yamaguchi, Musashino-shi, Tokyo (JP); Masashi Ota, Musashino-shi, Tokyo (JP); Kenya Suzuki, Musashino-shi, Tokyo (JP)

(21) Appl. No.: 18/258,863

(22) PCT Filed: Jan. 18, 2021
(86) PCT No.: PCT/JP2021/001487

§ 371 Date: Jun. 22, 2023

(51) Int. Cl. G01R 1/073; G01R 3/00; H05K 1/02; H05K 3/40; H05K 3/26

(52) U.S. Cl. CPC G01R 1/07342; G01R 3/00; H05K 1/0274; H05K 3/4038; H05K 3/26; H05K 2201/10121

(57) ABSTRACT

A probe card capable of simultaneously measuring both optical and electrical characteristics of an optoelectronic device is provided. A probe pin inserted into a via hole formed in a substrate and configured to measure the electrical characteristics and an optical fiber inserted into the via hole formed in the substrate and configured to measure the optical characteristics are provided.

### TECHNICAL FIELD

The present invention relates to a probe card, and more particularly, to a probe card capable of simultaneously measuring both optical and electrical characteristics of an optoelectronic device in which an optical element and an optical circuit are integrated and a method of producing the same.

### BACKGROUND ART

Semiconductor devices are produced by performing various processes on semiconductor wafers, forming a plurality of chips (or dies) on which electronic circuits are formed, and cutting the chips into a plurality of chips using a dicing saw. In addition, a plurality of semiconductor devices are collectively produced. In a semiconductor producing process, the electrical characteristics of each chip are measured using an inspection device constituted of a prober and a tester. A prober brings a probe pin of a probe card into contact with an electrode formed on each chip of a wafer fixed to a wafer chuck. A tester is electrically connected to a probe pin, applies a voltage or a current to an electronic circuit of each chip, and measures various electrical characteristics via the probe pin.

On the other hand, optoelectronic devices in which an electronic circuit, an optical element, and an optical circuit are integrated are mass-produced due to the progress of silicon photonics technology (for example, refer to NPL 1). Optoelectronic devices formed on silicon wafers need to measure the electrical characteristics of electronic circuits and the optical characteristics of optical elements and optical circuits. The optical characteristics are measured by optically coupling an optical element attached to a probe card with a grating coupler, an elephant coupler, or the like in an optical circuit formed on each chip in advance (for example, refer to NPL 2). Therefore, measurements of electrical and optical characteristics have been performed separately using different probe cards. In addition, in the measurement of the optical characteristics, the alignment between the optical element of the probe card and the optical circuit needs to be performed for each chip and a lot of time is spent on the inspection in the manufacturing process.

### CITATION LIST

### Non Patent Literature

[NPL 1] A. E. Lim et al., “Review of Silicon Photonics Foundry Efforts,” in IEEE Journal of Selected Topics in Quantum Electronics, vol. 20, No. 4, pp. 405 to 416, July to August 2014, Art No. 8300112, doi:10.1109/JSTQE.2013.2293274.
[NPL 2] J. De Coster et al., “Test-station for flexible semi-automatic wafer-level silicon photonics testing,” 2016 21th IEEE European Test Symposium (ETS), Amsterdam, 2016, pp. 1 to 6, doi:10.1109/ETS.2016.7519306.

### SUMMARY OF INVENTION

An object of the present invention is to provide a probe card capable of simultaneously measuring both optical and electrical properties of an optoelectronic device and a method of producing the same.

In order to achieve such an object, an embodiment of the present invention is a probe card which measures electrical and optical characteristics of an optoelectronic device including: a probe pin inserted into a via hole formed in a substrate and configured to measure the electrical characteristics; and an optical fiber inserted into a via hole formed in the substrate and configured to measure the optical characteristics.

Another embodiment is a method of producing a probe card which measures electrical and optical characteristics of an optoelectronic device formed on a wafer including: a step of forming a via hole in a substrate; a step of forming a metal plating film on the substrate for fixing a probe pin which measures the electrical characteristics; a step of inserting an optical fiber which measures the optical characteristics into the via hole and fixing the optical fiber to protrude slightly from a surface facing the wafer; a step of polishing a surface of the substrate facing the wafer; and a step of inserting the probe pin into the via hole and fixing the probe pin to a region in which the metal plating is formed.

### BRIEF DESCRIPTION OF DRAWINGS

FIG. 1 is a diagram showing a schematic configuration of an inspection device according to an embodiment of an invention.

FIG. 2 is a diagram showing a schematic configuration of a probe card according to the inspection device of the embodiment.

FIG. 3 is a diagram showing another example of the probe card according to the inspection device of the embodiment.

FIG. 4 is a diagram showing a preparing process of a probe card according to a first embodiment of the present invention.

FIG. 5 is a diagram showing a preparing process of a probe card according to a second embodiment of the present invention.

### DESCRIPTION OF EMBODIMENTS

Embodiments of the present invention will be described in detail below with reference to the drawings.

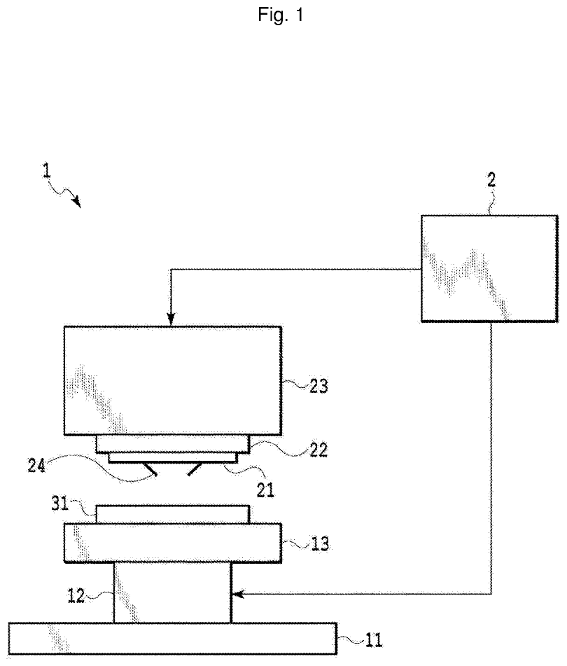

FIG. 1 shows a schematic configuration of an inspection device according to an embodiment of the present invention. The inspection device is composed of a prober 1 and a tester 2. A silicon wafer 31 on which an optoelectronic device to be inspected is formed is fixed to a wafer chuck 13 and moved in three axial directions using a driving mechanism 12 on a base 11. A probe card 21 is fixed to a test head 23 connected to the tester 1 via a circuit board 22. The tester 1 controls the driving mechanism 12 to bring the probe pins 24 of the probe card 21 into contact with the electrodes formed on the respective chips of the silicon wafer 31. The probe pins 24 are connected to the tester 1 via the circuit board 22 and the test head 23.

The probe pins 24 of the probe card 21 of the embodiment includes an electric probe for measuring electrical characteristics and an optical probe for measuring optical characteristics. Furthermore, the test head 23 includes an optical element optically coupled to the optical probe, an optical circuit, an optical/electric converter, and an electric/optical converter. In addition, the optical characteristics can be measured by exchanging electrical signals with the tester 1.

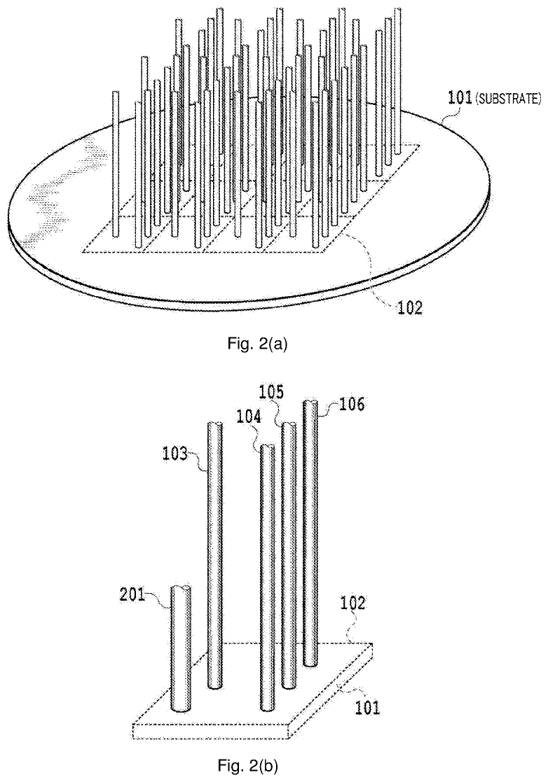

FIG. 2 shows a schematic configuration of a probe card according to the inspection device of the embodiment. As shown in FIG. 2(a), the probe card 21 has a configuration in which an electric probe and an optical probe are connected to a substrate 101 made of silicon (Si) or silica (SiO₂) for each region 102 corresponding to one chip of electronic circuits, optical elements, and optical circuits formed on a silicon wafer. The substrate 101 has a circular shape to match a shape of a silicon wafer to be measured.

FIG. 2(b) is an enlarged view of a region 102 corresponding to one chip and shows that an electric probe 201 and optical probes 103 to 106 are connected to each other. It is possible to simultaneously measure the electrical characteristics and optical characteristics of a plurality of chips present in the wafer using the probe card. Thus, the inspection process can be greatly reduced and the throughput in the producing process can be improved.

The optical probes 103 to 106 are optical fiber core wires having an outer diameter of 125 μm and are attached so that the optical axes thereof are perpendicular to a substrate surface of the substrate 101. The electrical probe 201 is a probe pin made of an alloy such as beryllium copper and is divided into a pipe and a contact pin (also referred to as a plunger) at a tip portion. In addition, various types of electric probes such as a structure in which a contact pin can be replaced, a structure in which a spring mechanism is installed in a pipe, and the like can be applied to the electrical probe 201.

The probe card of the embodiment is a so-called vertical probe card. In addition, although a pitch of probe pins of a general probe card for semiconductor devices is about 500 μm, it is possible to narrow a pitch to about 200 μm.

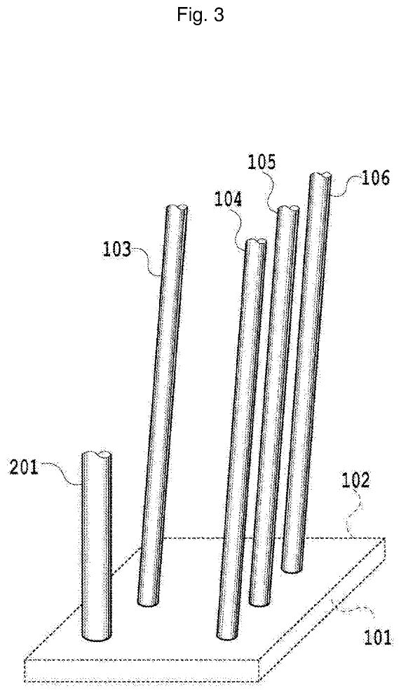

FIG. 3 shows another example of the probe card according to the inspection device of the embodiment. As described above, the optical characteristics are measured by optically coupling a grating coupler, an elephant coupler, and the like in the optical circuit formed on each chip in advance and the tip portions of the optical probes 103 to 106 attached to the probe card. Thus, an attachment angle of the optical probes 103 to 106 with respect to the substrate 101 is tilted from the vertical direction by aligning a direction of light emitted from an optical element such as a grating coupler in the optical circuit with the optical axis of the optical fiber.

The probe card of the embodiment is connected to the test head 23 via the circuit board 22 shown in FIG. 1 to perform inspection. Alignment between the probe card and the wafer is performed using, as an index, a coupling rate when emitted light from the optical elements in the optical circuit is coupled to end surfaces of the optical probes 103 to 106. As described above, a direction of emission of light from the optical element may be inclined obliquely upward of the substrate and an angle of the probe may also be inclined accordingly. Reflection on the end surface can be minimized as much as possible by inclining the end surface obliquely.

### First Embodiment

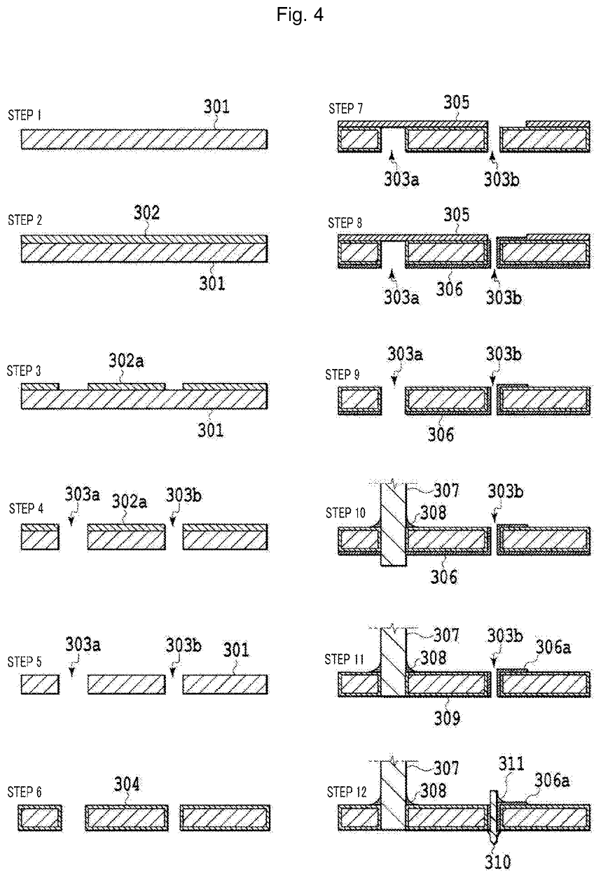

FIG. 4 shows a preparing process of a probe card according to a first embodiment of the present invention. A substrate 301 made of silicon (Si) or silica (SiO₂) is prepared (Step 1) and a resist 302 configured to form a via hole is applied (Step 2). After patterning a position for forming the via hole through photolithography (Step 3), the via hole is formed through etching (Step 4).

After removing the remaining resist 302a (Step 5), heat treatment is applied to form an insulating film 304 in the case of a silicon substrate (Step 6). A resist 305 configured to perform metal plating is applied and patterning is performed through photolithography (Step 7). Metal plating is applied to the inner wall of the via hole 303b for the electric probe and a solder region around the via hole 303b for fixing the probe pin of the electric probe. After forming a metal plating 306 (Step 8), the remaining resist 305 is removed (Step 9).

An optical fiber core wire 307 is inserted into the via hole 303a for the optical probe and fixed to an upper surface of the substrate, that is, a surface opposite to a surface facing the wafer using an adhesive 308 (Step 10). At this time, the end surface of the optical fiber core wire 307 slightly protrudes from the surface facing the wafer. A lower surface 309 of the substrate, that is, the surface facing the wafer is polished to remove the metal plating 306, and the end surfaces of the optical fiber core wires 307 are also polished to be flush (Step 11).

Finally, the probe pin 310 of the electric probe is inserted into the via hole 303b for the electric probe and fixed to the solder region of the remaining metal plating 306a using a solder 311 (Step 12).

Since a photolithography and etching process in the related art for forming an optical circuit in a silicon substrate can be applied to a formation method of the via hole according to the first embodiment, the processing accuracy is high and it is possible to easily realize a narrow pitch of the probe pins of the probe card.

### Second Embodiment

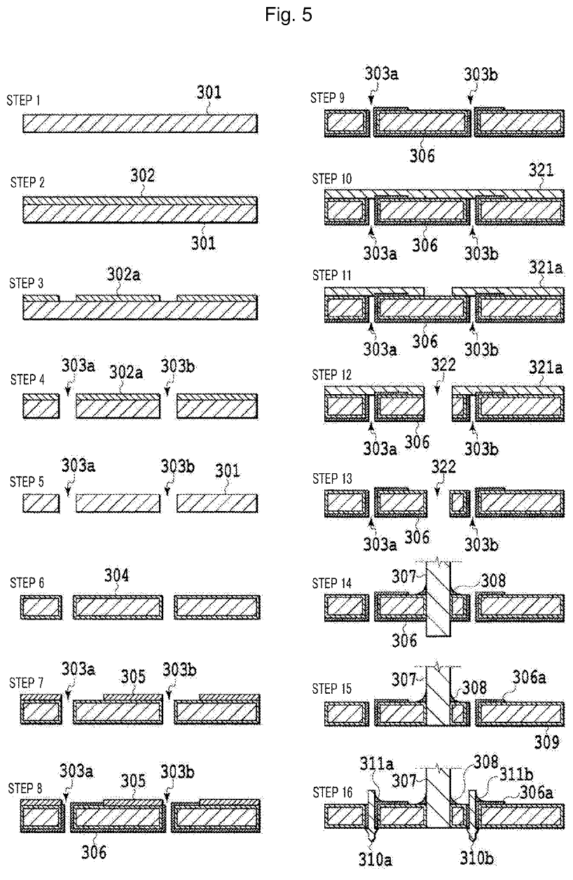

FIG. 5 shows a preparing process of a probe card according to a second embodiment of the present invention. A substrate 301 made of silicon (Si) or silica (SiO₂) is prepared (Step 1) and a resist 302 configured to form a via hole for an electric probe is applied (Step 2). After patterning a position for forming the via hole through photolithography (Step 3), the via hole is formed through etching (Step 4). Diameters of via holes 303a and 303b for electric probes are determined in consideration of a diameter of probe pins and a thickness of a metal-plated inner wall of the via hole.

After removing the remaining resist 302a (Step 5), heat treatment is applied to form an insulating film 304 in the case of a silicon substrate (Step 6). A resist 305 configured to perform metal plating is applied and patterning is performed through photolithography (Step 7). Metal plating is applied to inner walls of via holes 303a and 303b for electric probes and solder regions around the via holes 303a and 303b for fixing the probe pins of the electric probes. After forming the metal plating 306 (Step 8), the remaining resist 305 is removed (Step 9).

Subsequently, a resist 321 is applied for forming a via hole for the optical probe (Step 10). After patterning a position for forming the via hole through photolithography (Step 11), a via hole 322 is formed through etching (Step 12). The via hole 322 for the optical probe has a diameter of 125 μm.

The remaining resist 321a is removed (Step 13), the optical fiber core wire 307 is inserted into the via hole 322 for the optical probe and fixed to an upper surface of a substrate, that is, a surface opposite to a surface facing the wafer, using an adhesive 308 (Step 14). At this time, an end surface of the optical fiber core wire 307 slightly protrudes from the surface facing the wafer. A lower surface 309 of the substrate, that is, the surface facing the wafer is polished to remove the metal plating 306 and the end surfaces of the optical fiber core wires 307 are also polished to be flush (Step 15).

Finally, the probe pins 310a and 310b of the electric probe are inserted into the via holes 303a and 303b for the electric probe and fixed to the remaining solder regions of the metal plating 306a using solders 311a and 311b (Step 12).

In a method of forming a via hole according to the second embodiment, the formation of the via hole for an electric probe and the formation of the via hole for an optical probe are separate steps. As shown in FIG. 3, when the electric probe 201 is installed in the vertical direction with respect to the substrate 101 and the optical probes 103 to 106 are installed in the vertical direction with respect to the substrate 101, the former via hole is formed tilted from the vertical direction and the latter via hole is formed tilted from the vertical direction with respect to the substrate 101. According to the second embodiment, the directions of the via holes for the electric probe and the via holes for the optical probe can be changed and a degree of freedom in the formation direction of the via holes can be increased.

### Third Embodiment

A laser micro-fabrication process may be applied to formation of via holes for both the electrical probe and the optical probe. In this case, Steps 2 to 5 of the first embodiment and Steps 2 to 5 and Steps 10 to 13 of the second embodiment can be replaced with laser processing. For example, as shown in FIG. 3, the present invention is useful when a via hole for an optical probe is formed to be inclined from the vertical direction with respect to the substrate.

1. A probe card which measures electrical and optical characteristics of an optoelectronic device, comprising:
a probe pin inserted into a via hole formed in a substrate and configured to measure the electrical characteristics; and
an optical fiber inserted into a via hole formed in the substrate and configured to measure the optical characteristics.

2. The probe card according to claim 1, wherein an optical axis of the optical fiber is perpendicular to a substrate surface of the substrate.

3. The probe card according to claim 1, wherein an optical axis of the optical fiber is in a direction in which light is emitted from an optical element formed on the substrate.

4. The probe card according to claim 1, wherein the substrate is made of silicon (Si) or silica (SiO₂).

5. A method of producing a probe card which measures electrical and optical characteristics of an optoelectronic device formed on a wafer, comprising:
a step of forming a via hole in a substrate;
a step of forming a metal plating film on the substrate for fixing a probe pin which measures the electrical characteristics;
a step of inserting an optical fiber which measures the optical characteristics into the via hole and fixing the optical fiber to protrude slightly from a surface facing the wafer;
a step of polishing a surface of the substrate facing the wafer; and
a step of inserting the probe pin into the via hole and fixing the probe pin to a region in which the metal plating is formed.

6. The method of producing a probe card according to claim 5, wherein the substrate is made of silicon (Si) or silica (SiO₂), and
the step of forming a via hole in the substrate includes forming a via hole through photolithography and etching.

7. The probe card according to claim 2, wherein the substrate is made of silicon (Si) or silica (SiO₂).

8. The probe card according to claim 3, wherein the substrate is made of silicon (Si) or silica (SiO₂).
